(19) United States
(12) Patent Application Publication
(10) Pub. No.: US 2005/0047085 A1
(43) Pub. Date: Mar. 3, 2005

(54) High performance cooling systems

(76) Inventors: Nagui Mankaruse, Huntington Beach, CA (US); Magda Mankaruse, Huntington Beach, CA (US)

Correspondence Address: NAGUI MANKRUSE, P.O. BOX 1215, SUNSET BEACH, CA, 90742, US

(21) Appl. No.: 10/647,846

(22) Filed: Aug. 26, 2003

(51) Int. Cl. H05K 7/20

(52) U.S. Cl. 361/695

(57) ABSTRACT

The High performance cooling system s for cooling a heat source is disclosed. The cooling systems are air cooling systems, liquid cooling system, or space radiation cooling system. The air cooling system includes at least one high performance cold plate or cold plate, at least one plenum, at least one liquid pump, and at least one liquid to air heat exchanger. The liquid cooling system includes at least one high performance cold plate or cold plate, at least one plenum, at least one liquid pump, and at least one liquid to liquid heat exchanger. The space radiation cooling system includes at least at least one high performance cold plate, or cold plate, at least one plenum, at least one liquid pump, and at least one space radiator. Several different coolant fluids are available and can be used as a primary system coolant depending on the application.

The present invention relates generally to cooling systems, and more practically, to three cooling systems that are; air cooling liquid cooling, and radiation cooling. The cooling systems to be used with semiconductor devices and other heat-generating components and modules. The three cooling modes are for systems used in cooling semiconductor devices and modules.

### BACKGROUND OF THE INVENTION

1. Field of the Invention

The invention relates generally to systems cooling; air-cooling systems liquid-cooling systems, , and radiation cooling systems for high power dissipating electronic components or modules mounted on printed circuit boards or on a cold plate directly and more specifically a cost effective, high performance, high reliable cooling systems.

2. Description of Related Art

Generally, electronic devices are provided with a large number of heat-generating components and modules. As a result, in order to prevent the interior of the device from overheating, a cooling system has to be introduced. In recent years a cooling system for efficiently cooling the individual printed circuit boards that carry high heat dissipating electronic semi-conductor components or the semi-conductor components or modules mounted on the conductive surface of a cold plate. Conventionally, the cooling systems used in electronic devices are of two types: forced-air types and forced-liquid types. FIG. 1A is a diagram showing a conventional forced-air type cooling system 100, Gig 1B is a diagram showing a conventional forced-liquid type cooling system 200.

As shown in FIG. 1A, the air-cooled cooling system 100 has a heat sink 103 made from conductive material having a high rate of heat transmission such as aluminum or copper is provided on a heated part 101. The heat sink 103 is provided with a multiplicity of fins in order to increase the radiative effect. In the cooling system 100 a flow of air forcibly created by a fan 105 cools these fins and so cool the heated part 101.

Additionally, as shown in FIG. 1B, the liquid-cooled cooling system 200 has thermally conductive cold plates 203 provided in direct contact with the heated part 201. These cold plates 203 are positioned so as to contact a pipe 204 through which a liquid coolant 209 lo circulates opposite the heated part 201. When the liquid coolant 209 passes through the heat exchanger 207 it is heat exchanged and cooled, so the cold plates 203 can also be cooled and, accordingly, the heated part 201 is also cooled. This liquid-cooled cooling system 200 has a pump 205 and a heat exchanger 207 having a fan 208 to forcibly cool the heated part 201.

However, the above-described air-cooled cooling system 100 uses air to cool the heated member 101, so the rate of heat transmission is very low and the radiative effect is poor..

The liquid-cooled cooling system 200 described above, although it has good thermal conductivity, nevertheless still uses a pump 205 and a fan 208 and so is subject to the same disadvantages as those pertaining to the air-cooling system 100 described above, namely heat transmission is relatively low and radiative effect is poor.

The prior art teaches the use the heat dissipation devices in forming cooling systems for cooling electrical and electronic semi-conductor devices and modules, but does not teach such systems having the features of high performance, low cost, low specific weight, specific volume per unit power dissipation cooled and ease of manufacture. The present invention fulfills these needs and provides further related advantages as described in the following summary.

### SUMMARY OF THE INVENTION

It is a general object of the present invention to provide a high capacity cooling systems in which high power dissipation of high heat flux semiconductor devices or modules is accomplished using compact, cost effective cooling systems for different applications.

The apparatus and method of this invention provide cost-effective, high performance and modular way of producing cooling systems configuration that is capable of being produced and assembled through putting together core modules. The core modules are produced by mass production techniques or purchased from specialized producers and are ready to form the cooling system assembly. Substantial costs and delays in fabrication are minimized in addition to increase in reliability, which lower the breakdown risk level or increase the mean time between failures (MTBF). In addition a high heat dissipation of individual semiconductor devices or modules is achieved with low specific weight, volume and cost per unit power dissipation.

To realize the foregoing advantages, the invention in one form comprises a cold plate assembly for cooling heat sources on a printed circuit board, or individual semi-conductor components or modules mounted directly on cold plate i.e., the high power dissipating electronic components or modules. The cold plate assembly used is the high performance cold plate U.S. Pat. No. 6,411,512 or any other high performance cold plates with high power dissipating cooling capacity as required that is:

The air cooling system comprises four modules including: high performance cold plate or cold plates, plenum, liquid circulating pump, and liquid to air heat exchanger.

The liquid cooling system comprises four modules including: high performance cold plate or cold plates, plenum, liquid circulating pump, and liquid to liquid heat exchanger.

The space radiation cooling system comprises four modules including: high performance cold plate or cold plates, plenum, liquid circulating pump, and space radiator to exchange the heat to the outer space by radiation.

### BRIEF DESCRIPTION OF THE DRAWINGS

The accompanying drawings illustrate the present invention. In such drawings:

FIG. 2 is an air cooling system schematic;

FIG. 3 is a liquid cooling system schematic;

FIG. 4 is a space radiation cooling system schematic;

### DETAILED DESCRIPTION OF THE INVENTION

The above described drawing figures illustrate the invention in at least one of its preferred embodiments, which is further defined in detail in the following description.

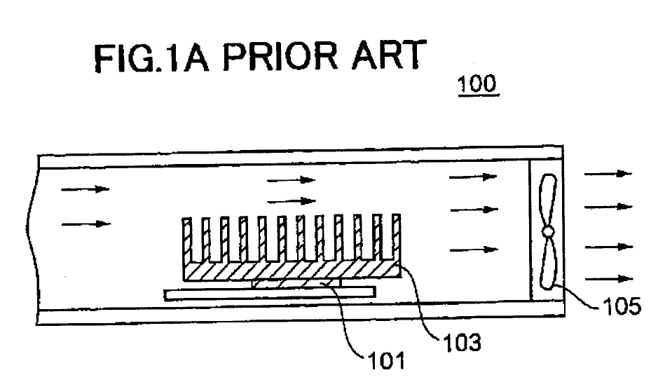

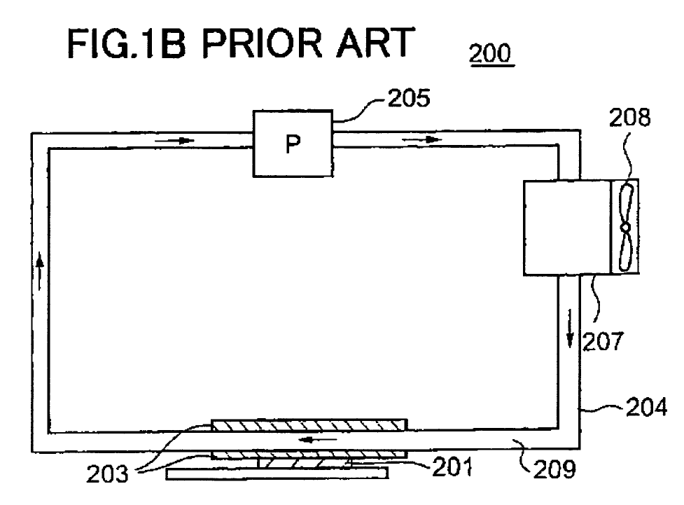

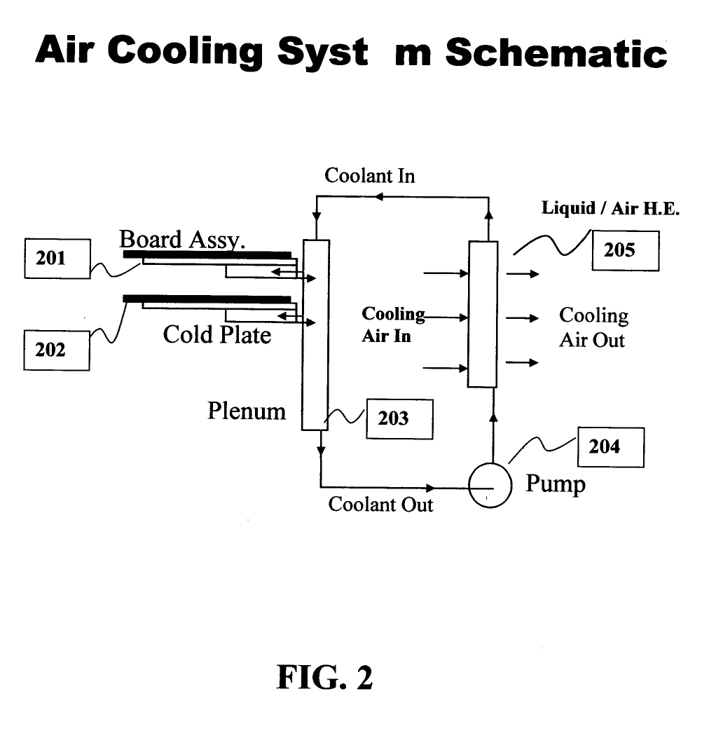

Referring to the FIG. 2, ‘Air Cooling System Schematic’ five modules are employed;

A conductive high performance cold plate 201, of the present invention;

A printed circuit board 202, with semiconductor devices ‘heat source’ mounted on the printed circuit board or heat dissipating semi-conductor devices, modules. The printed circuit board or heat dissipating module or modules are thermally attached to the cold plate or cold plates;

A plenum 203, to supply the cold plate or cold plates with cold coolant and collect returned hot coolant from two separated paths;

A circulating liquid pump 204 to receive the hot returned coolant from the cooled cold plate or cold plates through the plenum and deliver it to;

Liquid to air heat exchanger 205, in which the returned hot coolant is cooled by ambient air through exiting the liquid to air heat exchanger cold to be re-circulated back to the plenum 203 and then to enter the cold plate or cold plates.

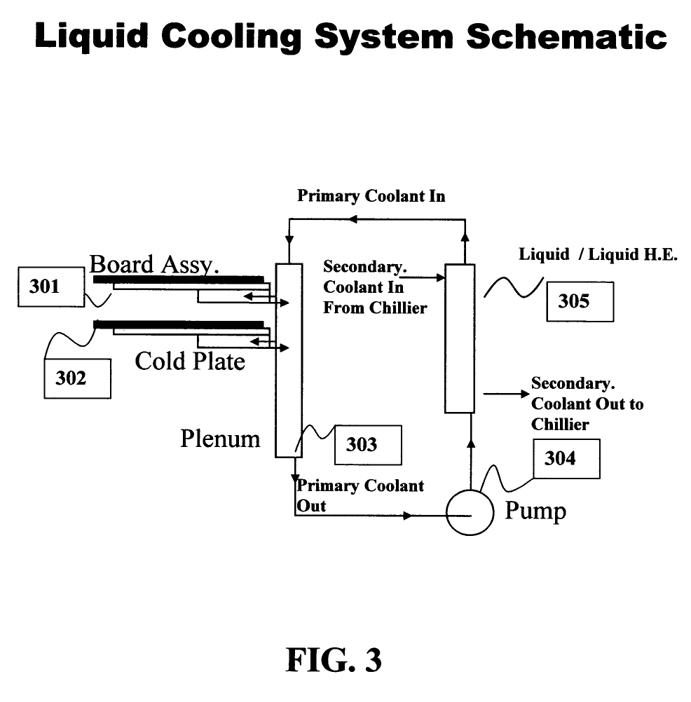

Referring to the FIG. 3, ‘Liquid Cooling System Schematic’ five modules are employed;

A conductive high performance cold plate 301, of the present invention;

A printed circuit board 302, with semiconductor devices ‘heat source’ mounted on the printed circuit board or heat dissipating modules. The printed circuit board or heat dissipating semi-conductor devices, module or modules are thermally attached to the cold plate or cold plates;

A plenum 303, to supply the cold plate or cold plates with cold coolant and collect returned hot coolant from two separated paths;

A circulating liquid pump 304 to receive the hot returned coolant from the cooled cold plate or cold plates through the plenum and deliver it to;

Liquid to liquid heat exchanger 305, in which the returned hot coolant is cooled by a secondary coolant through the exiting liquid to liquid heat exchanger cold to be re-circulated back to the plenum 303 and then to enter the cold plate or cold plates.

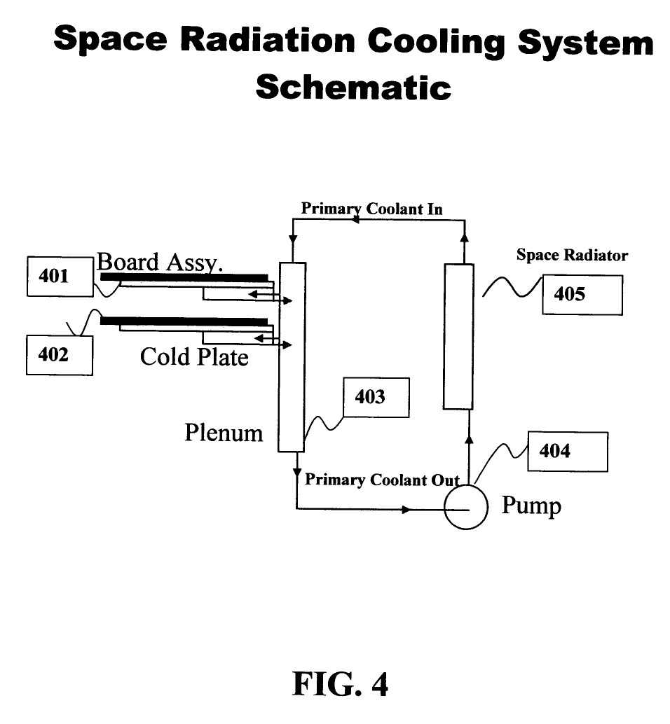

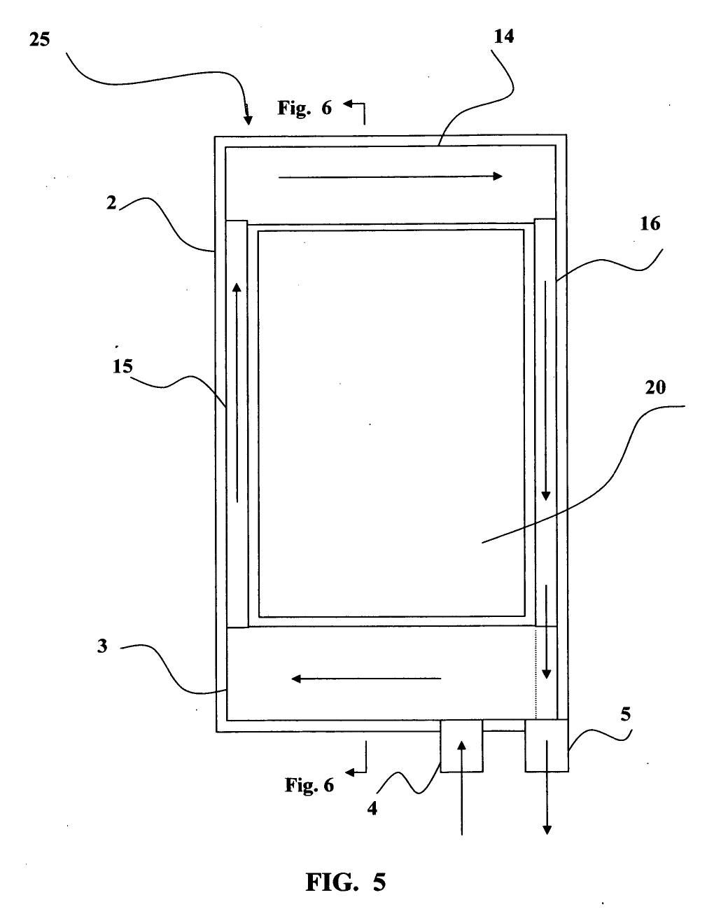

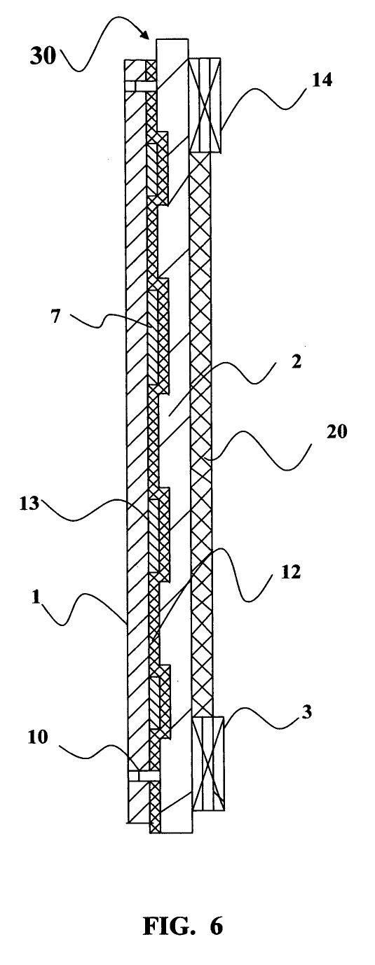

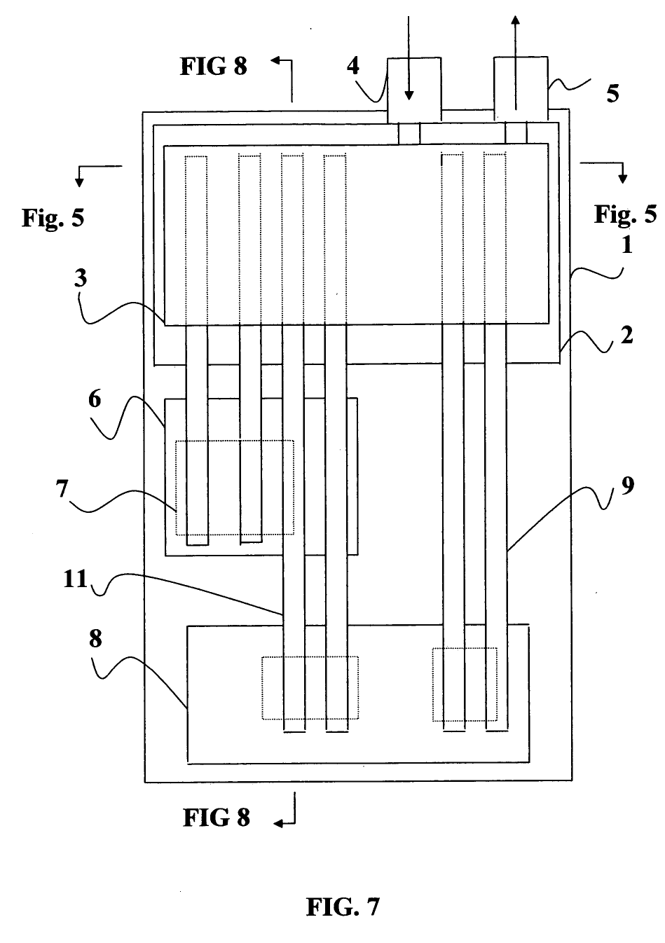

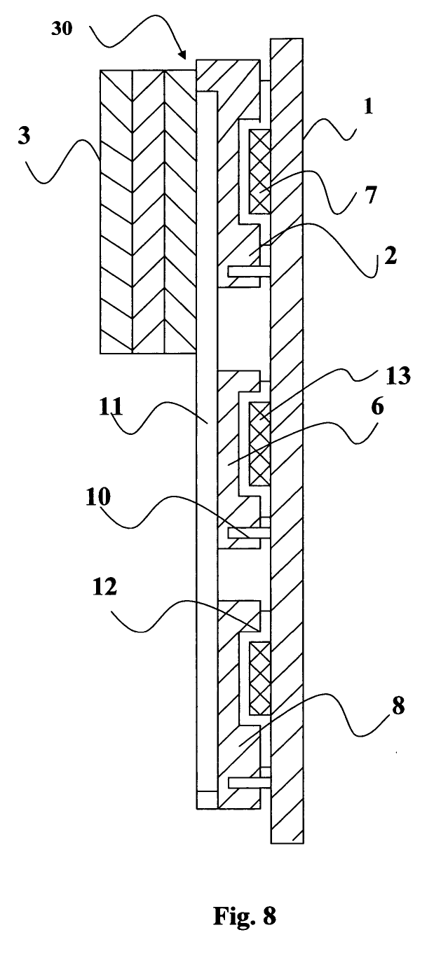

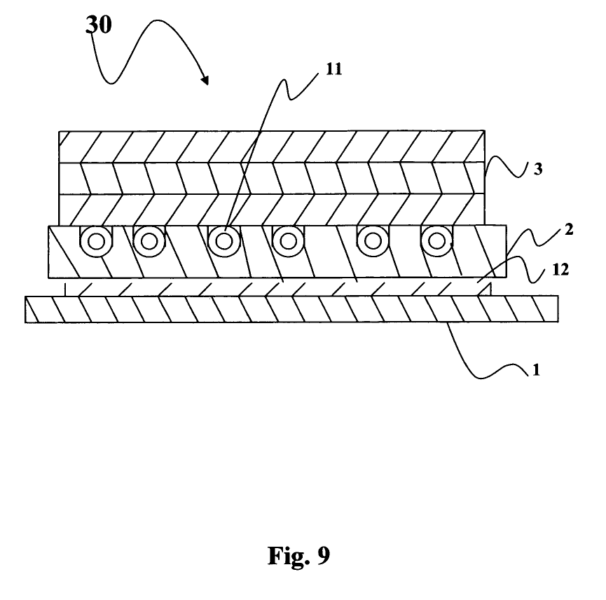

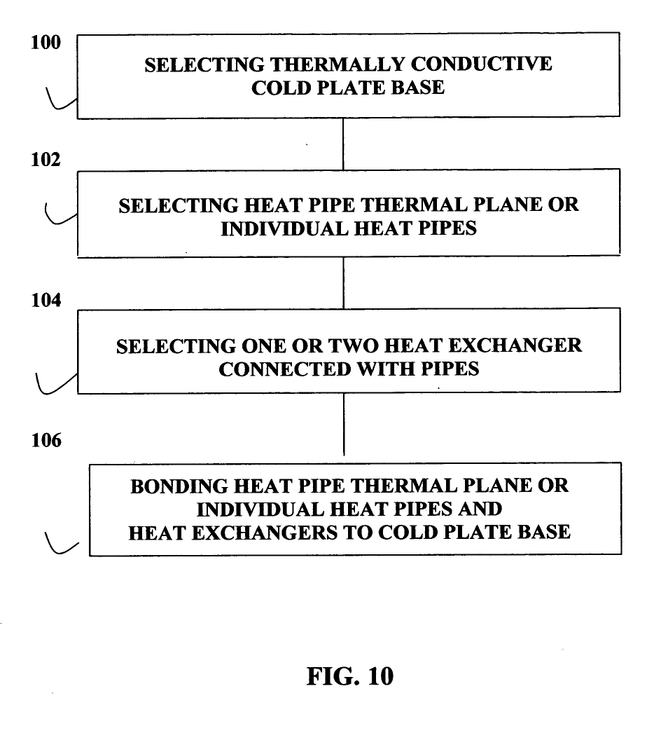

Referring to the FIG. 4, ‘Space Radiation Cooling System Schematic’ five modules are employed;

A conductive high performance cold plate 401, of the present invention;

A printed circuit board 402, with semiconductor devices ‘heat source’ mounted on the printed circuit board or heat dissipating modules. The printed circuit board or heat dissipating semi-conductor devices, module or modules are thermally attached to the cold plate or cold plates;

A plenum 403, to supply the cold plate or cold plates with cold coolant and collect returned hot coolant from two separated paths;

A circulating liquid pump 404 to receive the hot returned coolant from the cooled cold plate or cold plates through the plenum and deliver it to;

space radiator 405, in which the returned hot coolant is cooled by cold space radiator and exiting cold coolant to be re-circulated back to the plenum 403 and then to enter the cold plate or cold plates.

System primary coolants can be water, Ethylene Glycol Water, Polyalphaolyfin ‘PAO’, Ammonia, Methanol, Nitrogen or any other coolant that can accommodate the system and temperature limits and requirement.

While the invention has been particularly shown and described with reference to the preferred embodiments thereof, it will be understood by those skilled in the art that various changes in form and detail may be made therein without departing from the spirit and scope of the invention.

1-9. (Canceled)

10. A cooling assembly comprising
a cold plate assembly including at least one heat pipe and at least-one heat exchanger engaging and thermally connected to the at least one heat pipe and adapted for internally circulating a thermally conductive fluid therethrough;
heat generating electronic components in thermal conductivity with the at least one heat pipe;
a cooling system including a circuit having at least one circulating pump, at least one liquid to air heat exchanger and the heat exchanger engaging and thermally connected to the at least one heat pipe.

11. A cooling assembly comprising
a cold plate assembly including at least one heat pipe and at least one heat exchanger engaging and thermally connected to the at least one heat pipe and adapted for internally circulating a thermally conductive fluid therethrough;
heat generating electronic components in thermal conductivity with the at least one heat pipe;
a cooling system including a circuit having at least one circulating pump, at least one liquid to liquid heat exchanger and the heat exchanger engaging and thermally connected to the at least one heat pipe.

12. A cooling assembly comprising
a cold plate assembly including at least one heat pipe and at least one heat exchanger engaging and thermally connected to the at least one heat pipe and adapted for internally circulating a thermally conductive fluid therethrough;
heat generating electronic components in thermal conductivity with the at least one heat pipe;
a cooling system including a circuit having at least one circulating pump, at least one liquid to space radiator heat exchanger and the heat exchanger engaging and thermally connected to the at least one heat pipe.
